(19) United States
(12) Patent Application Publication
(10) Pub. No.: US 2007/0281218 A1
(43) Pub. Date: Dec. 6, 2007

(54) Dummy Phase Shapes To Reduce Sensitivity Of Critical Gates To Regions Of High Pattern Density

(76) Inventor: Howard S Landis, Underhill, VT (US)

Correspondence Address: LAW OFFICE OF DELIO & PETERSON, LLC., 121 WHITNEY AVENUE, NEW HAVEN, CT, 06510, US

(21) Appl. No.: 11/421,805

(22) Filed: Jun. 2, 2006

(51) Int. Cl. G06F 17/50; G03C 5/00; G03F 1/00

(52) U.S. Cl. 430/5; 716/19; 716/21; 430/394

(57) ABSTRACT

A method of generating dummy phase shapes in the layout of an alternating phase shift mask. The method comprises identifying a linewidth-sensitive feature and a large feature in the circuit design, and identifying a space therebetween. On the aItPSM mask layout there are provided opposing phase shifting shapes to project an image of the linewidth-sensitive feature and an adjacent dummy phase shifting shape corresponding in location to the space. The dummy phase shifting shape is disposed on the alternating phase shifting mask a distance sufficiently far from the at least two opposing phase shifting shapes, and from the corresponding location of the large feature in the design, such that light projected through the at least one dummy phase shifting shape by the lithographic system does not significantly affect the final projected images of the linewidth-sensitive feature and the large feature.

### BACKGROUND OF THE INVENTION

1. Field of the Invention

The present invention is directed to the manufacture of masks used in the lithographic production of integrated circuits and, in particular, to the manufacture of alternating phase shifting masks.

2. Description of Related Art

Polysilicon gate dimensional control is of critical importance for advanced semiconductor technologies. Two-mask alternating phase shift lithography offers improved resolution and dimensional control relative to competing one-mask solutions such as attenuated phase shift lithography. With alternating phase shift mask (altPSM) processing, a first phase mask is used to image the small, features in a design of critical dimension. As used herein, the term critical dimension refers to any dimension smaller than the smallest dimension that can be printed within a specified tolerance by a lithographic process without the need for a resolution enhancement technique such as alternating phase shift mask lithography. Two types of openings are created on the phase mask, in such a way that the light emerging from one type of opening is 180° out of phase with light emerging from the second type of opening. This phase variation may be achieved by modifying the length that a light beam travels through the mask material, for example, by recessing the mask to appropriate thinner and thicker depths. This results in the destructive interference of the light that cancels it out and prints the line or other shape with the desired critical dimension, such as the line width. The interference of alternating phase shapes allows smaller features to be imaged in photoresist than would otherwise be possible. A second block or trim mask using conventional opaque segments, made for example by employing chrome over glass (COG) techniques, is then used to expose the same photoresist layer, to trim the ends of some features rendered by the phase mask, and to image large features (such as decoupling capacitors) that are not easily resolved with the phase mask.

In all optical lithography tools, linewidth variations are induced by scattered light from nearby mask openings. This phenomenon is commonly referred to as optical flare. Known solutions to this problem are to restrict the mask pattern density near linewidth-sensitive critical features, so as to reduce the variation in optical flare in different portions of the layout. Restrictions on the minimum and maximum local density of gate features and on the closest approach of critical gates to regions of high and/or low density are used in the industry. However, these approaches limit the ability of designers to place large features, for example, decoupling capacitor near small features, for example, high-speed circuitry, with flexibly and at high density. Designers are then forced to use larger chip sizes and lower total decoupling capacitance than would otherwise be allowed or desired.

### SUMMARY OF THE INVENTION

Bearing in mind the problems and deficiencies of the prior art, it is therefore an object of the present invention to provide a method of lithographically imaging a circuit design which includes large feature and linewidth-sensitive features at higher density than presently possible with two mask systems.

It is another object of the present invention to provide an improved layout of an alternating phase shift mask used by a lithographic system to project an image of a circuit design which reduces restrictions on placement of designs, including a linewidth-sensitive feature spaced from a large feature.

A further object of the invention is to provide a method of lithographically projecting a circuit design that reduces linewidth variations caused by optical flare.

It is yet another object of the present invention to provide a method of generating dummy phase shapes in the layout of an alternating phase shift mask used by a lithographic system to project an image of a circuit design including a large feature and a nearby linewidth-sensitive feature.

Still other objects and advantages of the invention will in part be obvious and will in part be apparent from the specification.

The above and other objects, which will be apparent to those skilled in the art, are achieved in the present invention which is directed to in one aspect to a method of generating dummy phase shapes in the layout of an alternating phase shift mask used by a lithographic system to project an image of a circuit design. The design includes at least one large feature and at least one linewidth-sensitive feature spaced from the large feature. The method comprises identifying a linewidth-sensitive feature in the design, identifying a large feature in the design, and identifying a space between the linewidth-sensitive feature and the large feature. The method then includes providing on the layout of an alternating phase shift mask at least two opposing phase shifting shapes, whereby light projected through the at least two opposing phase shifting shapes projects an image of the linewidth-sensitive feature. There is also provided on the layout of the alternating phase shift mask at least one dummy phase shifting shape adjacent the at least two opposing phase shifting shapes. The at least one dummy phase shifting shape corresponds in location to the space between the linewidth-sensitive feature and the large feature. The dummy phase shifting shape is disposed on the alternating phase shifting mask a distance sufficiently far from the at least two opposing phase shifting shapes, and from the corresponding location of the large feature in the design, such that light projected through the at least one dummy phase shifting shape by the lithographic system does not significantly affect the final projected images of the linewidth-sensitive feature and the large feature.

In another aspect, the present invention is directed to a method of projecting an image of a circuit design, where the design includes at least one large feature and at least one linewidth-sensitive feature spaced from the large feature. The method comprises identifying a linewidth-sensitive feature in the design, a large feature in the design, and a space between the linewidth-sensitive feature and the large feature. The method also includes providing on the layout of an alternating phase shift mask: i) at least two opposing phase shifting shapes, whereby light projected through the at least two opposing phase shifting shapes projects an image of the linewidth-sensitive feature; and ii) at least one dummy phase shifting shape adjacent the at least two opposing phase shifting shapes, the at least one dummy phase shifting shape corresponding in location to the space between the linewidth-sensitive feature and the large feature. The dummy phase shifting shape is disposed on the alternating phase shifting mask a distance sufficiently far from the at least two opposing phase shifting shapes, and from the corresponding location of the large feature in the design, such that light projected through the at least one dummy phase shifting shape by the lithographic system does not significantly affect the final projected images of the linewidth-sensitive feature and the large feature. The method then includes providing on the layout of a block mask an opaque shape corresponding to the large feature. The method further includes creating an alternating phase shift mask from the layout of an alternating phase shift mask and a block mask from the layout of the a block mask. Subsequently, the method includes projecting light first through the alternating phase shift mask and subsequently through the block mask onto a wafer. Light projected through the at least two opposing phase shifting shapes on the alternating phase shift mask projects an image of the linewidth-sensitive feature and light projected through the opaque shape on the block mask project an image of the large feature. The dummy phase shifting shape is disposed on the alternating phase shifting mask a distance sufficiently far from the at least two opposing phase shifting shapes, and from the corresponding location of the large feature in the design such that light projected through the at least one dummy phase shifting shape by the lithographic system does not significantly affect the final projected images of the linewidth-sensitive feature and the large feature.

The at least one dummy phase shifting shape may comprise spaced, adjacent dummy phase shifting shapes of the same phase or of opposite phase. The at least one dummy phase shifting shape preferably occupies a majority of the space between the corresponding locations of the linewidth-sensitive feature and the large feature. The at least one dummy phase shifting shape may comprise a single dummy phase shifting shape. The at least one dummy phase shifting shape may surround the corresponding location of the large feature in the design.

### BRIEF DESCRIPTION OF THE DRAWINGS

The features of the invention believed to be novel and the elements characteristic of the invention are set forth with particularity in the appended claims. The figures are for illustration purposes only and are not drawn to scale. The invention itself, however, both as to organization and method of operation, may best be understood by reference to the detailed description which follows taken in conjunction with the accompanying drawings in which:

FIG. 1 is a plan view of an integrated circuit design showing spaced, adjacent large and linewidth-sensitive features.

FIG. 2 is a plan view of the layout of phase shifting shapes on an alternating phase shifting mask used to project the linewidth-sensitive feature of the circuit design of FIG. 1.

FIG. 3 is a plan view of the layout of opaque shapes on an alternating phase shifting mask used to project the large feature and trim the linewidth-sensitive feature of the circuit design of FIG. 1.

FIG. 4 is a plan view of the layout of phase shifting shapes on an alternating phase shifting mask made in accordance with the present invention to partially create the circuit design of FIG. 1.

FIG. 5 is a plan view of a variation of the alternating phase shifting mask of FIG. 4 made in accordance with the present invention.

### DESCRIPTION OF THE PREFERRED EMBODIMENT(S)

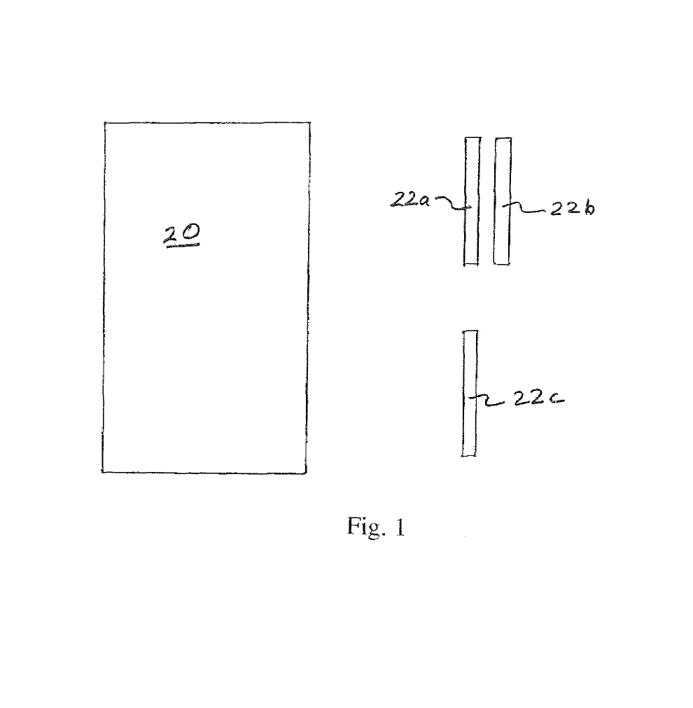

In describing the preferred embodiment of the present invention, reference will be made herein to FIGS. 1-5 of the drawings in which like numerals refer to like features of the invention.

The method of designing an alternating phase shifting mask of the present invention is most useful in connection with integrated circuit design features employed in semiconductor applications in which the linewidth sensitive feature is in the gate region of a transistor. In FIG. 1, there is depicted an exemplary portion of an integrated circuit layout design comprising segments that includes a large polysilicon feature 20 such as a decoupling capacitor, and adjacent narrow polysilicon gate structures 22a, 22b, 22c, for which dimensional control is of critical importance. These gate structures of the integrated circuit design have a critical width along their lengths, and are all parallel.

When these features are projected onto a wafer resist layer by a conventional two mask lithography system, dimensional variations from optical flare, or scattered light from nearby features, depend on the local density of nearby shapes. The term “nearby” as used in this context means a distance range from about one optical radius for the light energy used in the lithographic system, for example, about 650 nm (0.65 μm) for current lithography tools, to as much as 25 μm. Conventional layout ground rules requiring a large space between critical gates 22a, 22b, 22c and high-density regions such as those occupied by decoupling capacitors 20 are sometimes used to reduce the linewidth tolerance of critical gates due to optical flare. However, these rules reduce the achievable total decoupling capacitance, or increase the chip size, or both.

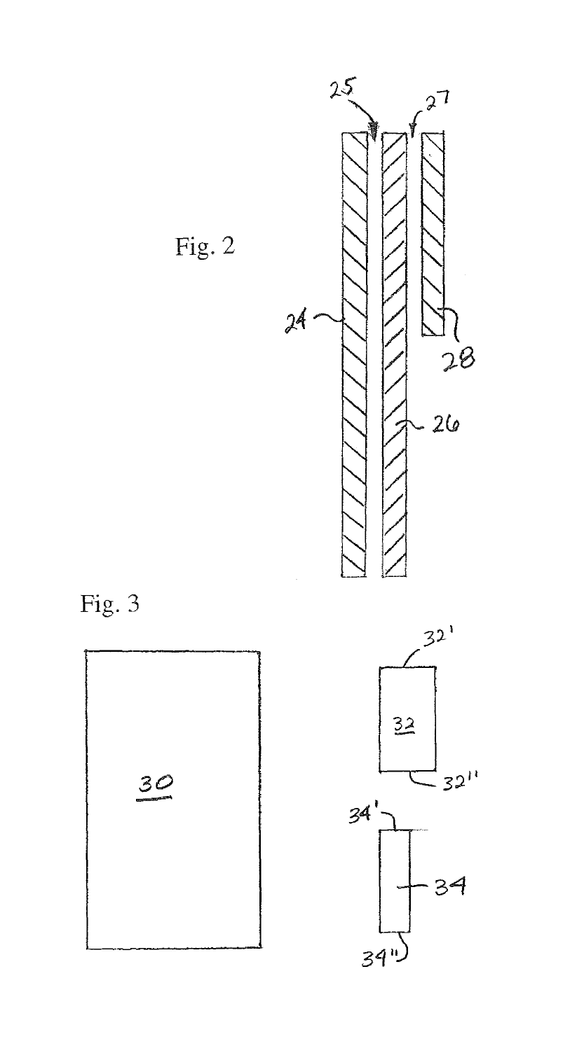

To permit smaller critical gates to be formed, there are provided altPSM shapes or segments to form the critical dimensions of the circuit features. FIG. 2 depicts a portion of an altPSM mask layout in which altPSM shapes or segments 24, 26 and 28 are intended to transmit the light projected by the lithographic imaging system. These light-transmitting shapes have intermediate spaces 25, 27 that correspond to the locations of the gate segments shown in FIG. 1, with space 25 being aligned along the corresponding location of gate segments 22a and 22c and space 27 being aligned along the corresponding location of gate segment 22b. The difference in degree of phase shifting is indicated by the direction of diagonal line shading in the figures. As shown in FIG. 2, phase shifting shapes 24 and 28 (with diagonal line shading in one direction) impart a 0° phase shift and shape 26 (with diagonal line shading in the opposite direction), between shapes 24 and 28, imparts a 180° phase shift. Likewise, if shapes 24 and 28 imparted a 90° phase shift to the light, shape 26 may impart a 270° phase shift to the light. It is necessary only that the light beams from the two adjacent shapes be 180° out of phase, so that their electric field vector will be of equal magnitude, but point in exactly the opposite direction, and any interaction between these overlapping light beams results in perfect cancellation. As is known, this optical interference effect permits smaller critical gate segments 22a, 22b, 22c to be formed using alternating phase shapes than would be possible with other lithographic processes. With previous altPSM layouts, there is no need to use phase shifting shapes to form large features such as the decoupling capacitor of FIG. 1, since it contains no critical dimensions.

FIG. 3 shows the opaque shapes on a block or trim mask used as the second mask, along with an altPSM mask, in a lithographic projection system. The block mask may be made, for example, by depositing chrome over a glass substrate. This second mask has large opaque shape 30 of corresponding configuration and location to image the large decoupling capacitor 20 and smaller opaque shapes 32, 34 used to trim the ends of the gate segments of FIG. 1. Opaque shape ends 32′, 32″ trim the ends of the lengths of gate segments 22a, 22b, while opaque shape ends 34′, 34″ trim the ends of the lengths of gate segment 22c.

The polarity masks used in altPSM lithography is such that phase shapes, for example, 0-degree and 180-degree phase shifting features, create spaces between gates, while opaque block shapes correspond to the gate structures or other polysilicon features themselves.

In accordance with the present invention, dummy altPSM shapes are placed in otherwise-empty space between the locations of spaced features of the circuit design, for example, between decoupling capacitors and nearby linewidth sensitive features. It has been found that, to first order, the dummy altPSM shapes do not affect the resist image for the decoupling capacitors or adjacent critical features. Dummy 0° and 180° phase shifting shapes expose the photoresist region adjacent or between decoupling capacitors with the first altPSM mask, and that same region would be exposed again by virtue of openings in the second block mask between the opaque shapes that correspond to the decoupling capacitors themselves. However, in the method of the present invention, the optical flare would be made more uniform, with the double-exposure compensating for the general deficit of scattered light in the vicinity of large high density features such as decoupling capacitors.

For example, if the maximum allowed polysilicon density is 70%, then 30% of the area occupied by a decoupling capacitor unit cell is empty space, and therefore available for dummy 0° and 180° phase shifting shapes or segments. If it is assumed that one large dummy 0° or 180° phase shifting shape essentially fills the channel between decoupling capacitors, the effective density of the decoupling capacitor could be reduced to just over 40%, thereby permitting some space between the dummy shapes and the decoupling capacitor itself for misalignment of the two masks. If it is assumed that an alternating pattern of dummy 0° or 180° phase shifting shape openings essentially fill the channel between decoupling capacitors, the effective density of the decoupling capacitor could be reduced to just over 46%. This assumes a dummy shape pattern that would produce a gate density of 20% if not trimmed by an opaque shape.

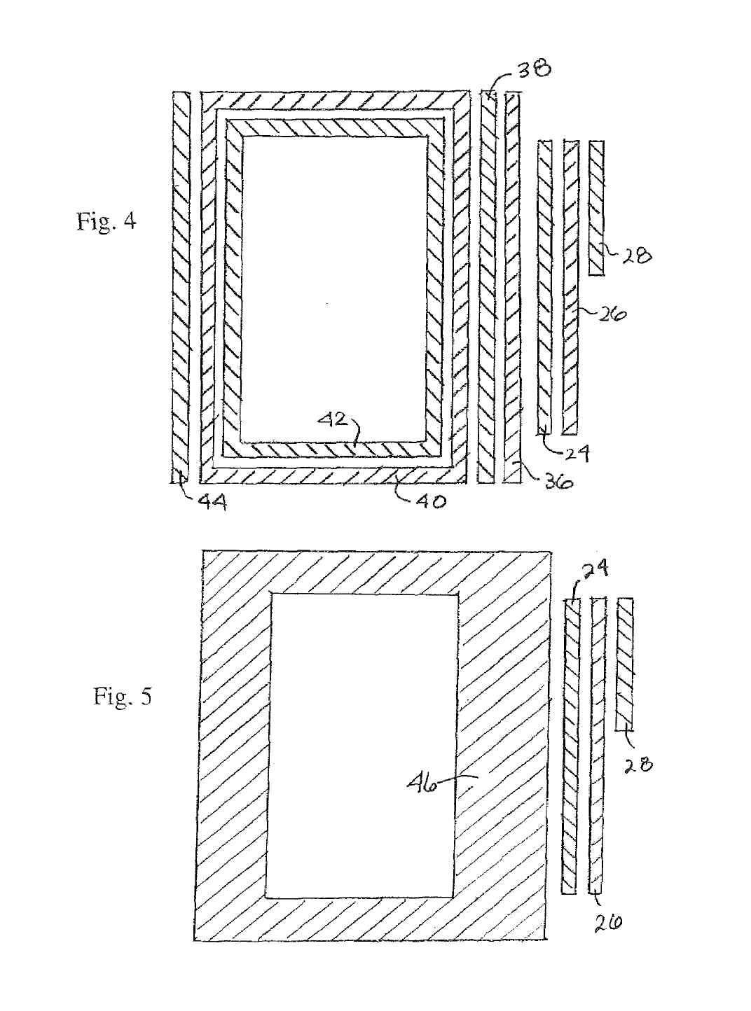

In FIG. 4, there is shown the layout of an altPSM for the circuit design of FIG. 1 made in accordance with the present invention. Nearby phase shifting shapes 40 and 42 are dummy phase shifting shapes surrounding the location corresponding to large polysilicon feature 20 of the circuit design (FIG. 1). Nearby phase shifting shapes 36 and 38 are between the locations corresponding to large polysilicon feature 20 and gates 22a, 22b, 22c of the circuit design. Nearby phase shifting shape 44 is between the locations corresponding to large polysilicon feature 20 and another large polysilicon feature (not shown in FIG. 1). Shapes 38, 42 and 44 impart a 0° phase shift while shapes 36 and 40 impart a 180° phase shift to the projected light.

To first order, when combined with the block mask of FIG. 3, the phase shifting shapes illustrated in FIG. 4 would produce essentially the same features of the circuit design of FIG. 1 as would be produced by the more conventional phase shapes shown in FIG. 2. However, because the total amount of scattered light-counting the exposures from both the altPSM and block masks—is much higher around the location corresponding to decoupling capacitor 20 as a result of light transmission through dummy phase shapes 36, 38, 40, 42 and 44, the optical flare in the vicinity of decoupling capacitor 20 is much closer to the optical flare elsewhere in the circuit design. This more uniform optical flare results in a smaller variation in the final width dimension of nearby critical gate segments 22a, 2b, 22c across a typical design. This improved process tolerance may be retained for improved gate control, or may be used to loosen layout constraints for critical gates in the vicinity of dense decoupling capacitor.

A modification of the altPSM layout of FIG. 4 is shown in FIG. 5. Instead of multiple dummy phase shifting shapes imparting adjacent opposite phase shifts, a single dummy phase shifting shape 46 is adjacent to and surrounds the corresponding location of large feature decoupling capacitor 20 of the circuit design. Although shown as a 180° phase shifting shape, dummy shape may impart a 0° or any other phase shifts. Moreover, the adjacent dummy phase shapes of FIG. 4 do not need to alternate between 0° and 180° phase shifting shapes. Instead, dummy phase shapes of the same phase shifting type may be placed adjacent to one another. For example, in FIG. 4, adjacent dummy phase shapes 40 and 44 may be made to have the same degree of phase shift, as may dummy shapes 40 and 42, 40 and 38, or 36 and 38. The constraint that adjacent phase shape be of alternating type, which is required for printing small gates, is not required for dummy phase shapes, since the region between dummy phase shapes is not required to print. Rather, it will be thoroughly exposed with the second block mask.

By computational analysis of the design shapes associated with gate structures in a semiconductor layout, dummy phase shapes as in FIGS. 4 and 5 can be readily generated using the following method. First, identify large features in the design, and identify spaces within or around dense regions of the design, for example, between the decoupling capacitor and gates segments of FIG. 1. Then, place dummy phase shapes in the empty spaces surrounding the previously identified large features or in the previously identified spaces in dense regions on the phase mask. Space the dummy phase shapes sufficiently far from the large features and from critical gates to insure that the dummy shapes do not adversely affect other shapes in the neighborhood.

After the mask layouts are completed, the masks themselves are rendered or formed by well-known techniques. The masks are then used in otherwise conventional photolithography to expose the circuit images onto the resist layer on a wafer, after which the resist layer is developed and etched, and the circuit features are formed on the wafer.

In addition to the circuit features described above, the mask structures and methods of the present invention may also be applied to any other layer in a semiconductor design that is rendered with an altPSM process.

Thus, the present invention provides an improved layout of an alternating phase shift mask used by a lithographic system to project an image of a circuit design which reduces restrictions on placement of designs including a linewidth-sensitive feature spaced from a large, non-critical dimension feature. In particular, by generating dummy phase shapes in the layout of an alternating phase shift mask, the invention provides a method of lithographically projecting a circuit design that reduces linewidth variations caused by optical flare.

While the present invention has been particularly described, in conjunction with a specific preferred embodiment, it is evident that many alternatives, modifications and variations will be apparent to those skilled in the art in light of the foregoing description. It is therefore contemplated that the appended claims will embrace any such alternatives, modifications and variations as falling within the true scope and spirit of the present invention.

Thus, having described the invention, what is claimed is:

1. A method of generating dummy phase shapes in the layout of an alternating phase shift mask used by a lithographic system to project an image of a circuit design, the design including at least one large feature and at least one linewidth-sensitive feature spaced from the large feature, the method comprising:
identifying a linewidth-sensitive feature in the design;
identifying a large feature in the design;
identifying a space between the linewidth-sensitive feature and the large feature;
providing on the layout of an alternating phase shift mask at least two opposing phase shifting shapes, whereby light projected through the at least two opposing phase shifting shapes projects an image of the linewidth-sensitive feature; and
providing on the layout of the alternating phase shift mask at least one dummy phase shifting shape adjacent the at least two opposing phase shifting shapes, the at least one dummy phase shifting shape corresponding in location to the space between the linewidth-sensitive feature and the large feature, the dummy phase shifting shape being disposed on the alternating phase shifting mask a distance sufficiently far from the at least two opposing phase shifting shapes, and from the corresponding location of the large feature in the design, such that light projected through the at least one dummy phase shifting shape by the lithographic system does not significantly affect the final projected images of the linewidth-sensitive feature and the large feature.

2. The method of claim 1 wherein the at least one dummy phase shifting shape comprises spaced, adjacent dummy phase shifting shapes of opposite phase.

3. The method of claim 1 wherein the at least one dummy phase shifting shape comprises spaced, adjacent dummy phase shifting shapes of the same phase.

4. The method of claim 1 wherein the at least one dummy phase shifting shape occupies a majority of the space between the corresponding locations of the linewidth-sensitive feature and the large feature.

5. The method of claim 4 wherein the at least one dummy phase shifting shape comprises spaced, adjacent dummy phase shifting shapes of opposite phase.

6. The method of claim 4 wherein the at least one dummy phase shifting shape comprises spaced, adjacent dummy phase shifting shapes of the same phase.

7. The method of claim 1 wherein the at least one dummy phase shifting shape comprises a single dummy phase shifting shape.

8. The method of claim 1 wherein the at least one dummy phase shifting shape comprises a single dummy phase shifting shape occupying a majority of the space between the corresponding locations of the linewidth-sensitive feature and the large feature.

9. The method of claim 1 wherein the at least one dummy phase shifting shape surrounds the corresponding location of the large feature in the design.

10. The method of claim 9 wherein the at least one dummy phase shifting shape comprises spaced, adjacent dummy phase shifting shapes of opposite phase.

11. A method of projecting an image of a circuit design, the design including at least one large feature and at least one linewidth-sensitive feature spaced from the large feature, the method comprising:
identifying a linewidth-sensitive feature in the design, a large feature in the design, and a space between the linewidth-sensitive feature and the large feature;
providing on the layout of an alternating phase shift mask i) at least two opposing phase shifting shapes, whereby light projected through the at least two opposing phase shifting shapes projects an image of the linewidth-sensitive feature; and ii) at least one dummy phase shifting shape adjacent the at least two opposing phase shifting shapes, the at least one dummy phase shifting shape corresponding in location to the space between the linewidth-sensitive feature and the large feature, the dummy phase shifting shape being disposed on the alternating phase shifting mask a distance sufficiently far from the at least two opposing phase shifting shapes, and from the corresponding location of the large feature in the design, such that light projected through the at least one dummy phase shifting shape by the lithographic system does not significantly affect the final projected images of the linewidth-sensitive feature and the large feature;
providing on the layout of a block mask an opaque shape corresponding to the large feature;
creating an alternating phase shift mask from the layout of the an alternating phase shift mask;
creating a block mask from the layout of the a block mask; and
projecting light first through the alternating phase shift mask and subsequently through the block mask onto a wafer, whereby light projected through the at least two opposing phase shifting shapes on the alternating phase shift mask projects an image of the linewidth-sensitive feature and light projected through the opaque shape on the block mask project an image of the large feature, and whereby the dummy phase shifting shape is disposed on the alternating phase shifting mask a distance sufficiently far from the at least two opposing phase shifting shapes, and from the corresponding location of the large feature in the design such that light projected through the at least one dummy phase shifting shape by the lithographic system does not significantly affect the final projected images of the linewidth-sensitive feature and the large feature.

12. The method of claim 11 wherein the at least one dummy phase shifting shape comprises spaced, adjacent dummy phase shifting shapes of opposite phase.

13. The method of claim 11 wherein the at least one dummy phase shifting shape comprises spaced, adjacent dummy phase shifting shapes of the same phase.

14. The method of claim 11 wherein the at least one dummy phase shifting shape occupies a majority of the space between the corresponding locations of the linewidth-sensitive feature and the large feature.

15. The method of claim 14 wherein the at least one dummy phase shifting shape comprises spaced, adjacent dummy phase shifting shapes of opposite phase.

16. The method of claim 14 wherein the at least one dummy phase shifting shape comprises spaced, adjacent dummy phase shifting shapes of the same phase.

17. The method of claim 11 wherein the at least one dummy phase shifting shape comprises a single dummy phase shifting shape.

18. The method of claim 11 wherein the at least one dummy phase shifting shape comprises a single dummy phase shifting shape occupying a majority of the space between the corresponding locations of the linewidth-sensitive feature and the large feature.

19. The method of claim 11 wherein the at least one dummy phase shifting shape surrounds the corresponding location of the large feature in the design.

20. The method of claim 19 wherein the at least one dummy phase shifting shape comprises spaced, adjacent dummy phase shifting shapes of opposite phase.
